(19) United States
(12) Patent Application Publication
(10) Pub. No.: US 2025/0357154 A1
(43) Pub. Date: Nov. 20, 2025

(54) SELECTIVE PERIODIC EDGE DEPOSITION AND ETCH

(71) Applicant: Applied Materials, Inc., Santa Clara, CA (US)

(72) Inventors: Chen-Yao CHAO, Santa Clara, CA (US); Seng-Hoe TAN, Singapore (SG); Zang KEYAN, Singapore (SG); Kazuyoshi KOBASHI, Santa Clara, CA (US); Ryan Sungbin HU, Santa Clara, CA (US); Kuan Chien SHEN, Sunnyvale, CA (US); Masato ISHII, Sunnyvale, CA (US)

(21) Appl. No.: 18/663,463

(22) Filed: May 14, 2024

(51) Int. Cl. H01L 21/67; H01L 21/20; H01L 21/687

(52) U.S. Cl. CPC H01L 21/67069; H01L 21/20; H01L 21/67098; H01L 21/68742; H01L 21/68764

(57) ABSTRACT

Aspects of the disclosure provide substrate processing system and method of substrate processing. The substrate processing system is applicable for use in semiconductor manufacturing and includes a chamber comprising a first inlet port to supply one or more process gases to a processing volume, a substrate support disposed in the processing volume and operable to rotate a substrate disposed on the substrate support, and a controller to cause a flow of one or more process gases supplied to the processing volume via the first inlet port to change based on an angle of rotation of the substrate. The flow of one or more process gases supplied to the processing volume changes between a first flow rate and a second flow rate, wherein the first flow rate is greater than the second flow rate.

### BACKGROUND

### Field

Embodiments of the present disclosure generally relate to an epitaxial deposition/etching chambers and methods for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposits films of various materials on a surface of a substrate in a processing chamber. During processing, various parameters can affect the uniformity of material deposited on the substrate.

However, operations (such as epitaxial deposition or etching operations) can be long, expensive, and inefficient, and can have limited capacity and throughput. Moreover, hardware can involve relatively large dimensions that occupy higher footprints in manufacturing facilities. Additionally, processing can involve nonuniformities, which can involve hindered device performance and/or reduced throughput. For example, activation of gases can be limited and/or can involve non-uniform activation, which can cause limited and/or non-uniform film growth, particularly at the edge of the substrate. The activation of gases can be limited, for example, at relatively low processing temperatures for device production (such as complementary field-effect transistor (CFET) devices). Moreover, relatively higher processing temperatures can involve unintended dopant diffusion and/or hindered device performance. Therefore, a need exists for improved apparatuses and methods in semiconductor processing.

### SUMMARY

Embodiments of the present disclosure generally relate to an epitaxial deposition/etching chambers and methods for semiconductor manufacturing.

In one embodiment, a substrate processing system is disclosed. The substrate processing system is applicable for use in semiconductor manufacturing and includes a chamber comprising a first inlet port to supply one or more process gases to a processing volume, a substrate support disposed in the processing volume and operable to rotate a substrate disposed on the substrate support, and a controller to cause a flow of one or more process gases supplied to the processing volume via the first inlet port to change based on an angle of rotation of the substrate.

In another embodiment, a method is disclosed. The method of substrate processing includes supplying one or more process gases to a processing volume of a chamber. A substrate is rotated within the processing volume and a flow of the one or more process gases is changed between a first flow rate and a second flow rate based on an angle of rotation of the substrate. The second flow rate is lower than the first flow rate. One or more layers are formed on the substrate with the one or more process gases.

In yet another embodiment, a method is disclosed. The method includes supplying one or more process gases to a processing volume of a chamber. The one or more process gases is flowed over a substrate and the substrate is rotated within the processing volume. A laser beam is directed from a laser to an edge region of the substrate. The edge region is at a radius of greater than 145 mm from a center of the substrate. A power of the laser beam is changed between a first power level and a second power level based on an angle of rotation of the substrate. The first power level is higher than the second power level. One or more layers are formed on the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic cross-sectional view of a chamber, according to embodiments.

FIG. 1B is a schematic, top cross-sectional view of the chamber

FIG. 2A is a graph of a sequential quadrant flow scheme and a formation resultant region on a substrate, according to embodiments.

FIG. 2B is a graph of an alternate quadrant flow scheme and a formation resultant region on a substrate, according to embodiments.

FIG. 2C is a graph of a single quadrant per cycle flow scheme and a resultant formation region on a substrate, according to embodiments.

FIG. 3A is a graph of a sequential square pulse scheme and a resultant formation region on a substrate, according to embodiments.

FIG. 3B is a graph of a sequential sinusoidal pulse scheme and a resultant formation region on a substrate, according to embodiments.

FIG. 3C is a graph of an alternate sinusoidal pulse scheme and a resultant formation region on a substrate, according to embodiments.

FIG. 4 is a flow diagram of a method of processing a substrate, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to an epitaxial deposition/etching chambers and methods for semiconductor manufacturing. In one aspect of the disclosure, a method is disclosed. The method include supplying a one or more process gases in a processing volume of a chamber. In some embodiments, a flow of one or more process gases over the substrate is toggled between a first state and a second state based on an angle of rotation of the substrate. In some embodiments, a treatment laser substrate is toggled between a first state and a second state based on an angle of rotation of the substrate to heat the one or more process gases. One or more layers are formed on the substrate.

The disclosure contemplates that terms such as “couples,” “coupling,” “couple,” and “coupled” may include but are not limited to welding, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling. The disclosure contemplates that terms such as “couples,” “coupling,” “couple,” and “coupled” may include operable coupling such as electric coupling and/or fluidly coupling.

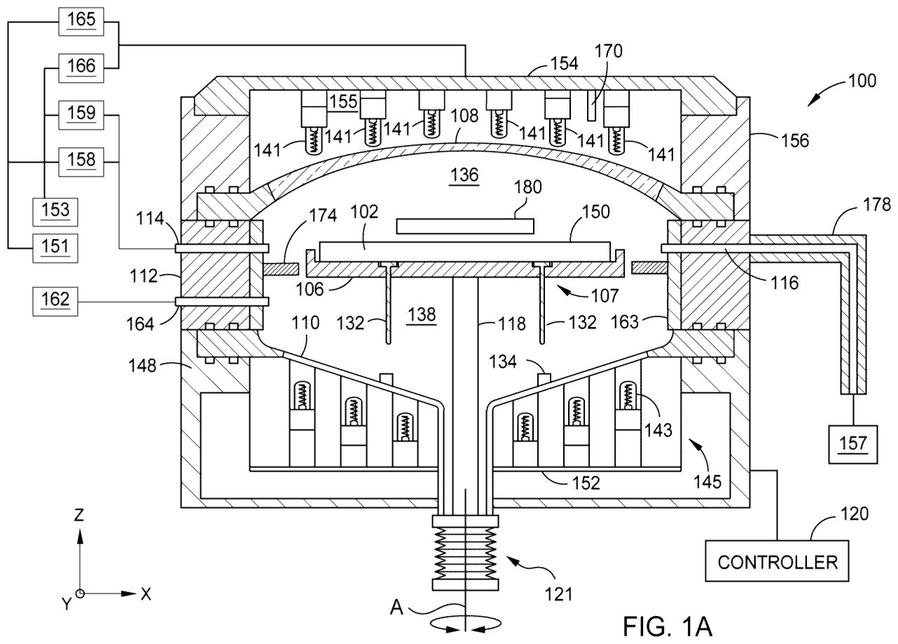

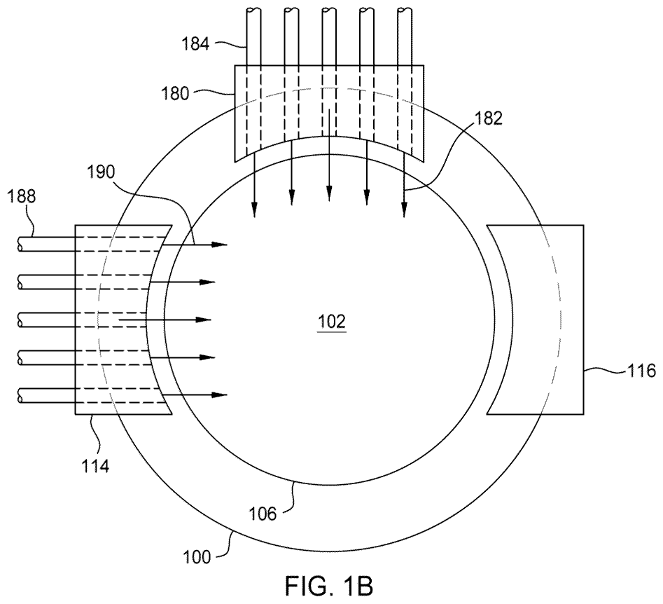

FIG. 1A is a schematic cross-sectional view of a chamber 100, according to one implementation. FIG. 1B is a schematic, top cross-sectional view of the chamber 100. The chamber 100 may be an epitaxial chamber or an epitaxial etching chamber. The chamber 100 is utilized to grow an epitaxial film on a substrate, such as a substrate 102. The chamber 100 creates a cross-flow of precursors across a top surface 150 of the substrate 102.

The chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108, a lower window 110, a plurality of upper lamps 141, and a plurality of lower lamps 143. As shown, a controller 120 is in communication with the chamber 100 and is used to control operations and methods, such as those described herein. In some embodiments, the controller 120 includes an encoder configured to measure the rotational position of the substrate 102 within the chamber 100. The upper window 108 can be convex as shown in FIG. 1 (such as when the chamber is used at a pressure below an atmospheric pressure), or the upper window 108 can be flat or concave (such as when the chamber 100 is used with the atmospheric pressure).

The substrate support 106 is disposed between the upper window 108 and the lower window 110. The plurality of upper lamps 141 are disposed between the upper window 108 and a lid 154. The plurality of upper lamps 141 form a portion of the upper lamp module 155. The lid 154 can include a plurality of sensors (not shown) disposed therein for measuring a temperature within the chamber 100. The plurality of lower lamps 143 are disposed between the lower window 110 and a floor 152. The plurality of lower lamps 143 form a portion of a lower lamp module 145. In the illustrated embodiment, the upper window 108 is an upper dome. In some embodiments, the upper window 108 is formed of an energy transmissive material, such as quartz. In the illustrated embodiment, the lower window 110 is a lower dome. In some embodiments, the lower window 110 is formed of an energy transmissive material, such as quartz.

In some embodiments, a treatment laser 170 may be disposed between the upper window 108 and the lid 154. The treatment laser 170 may be positioned over an edge region of the substrate 102. In some embodiments, the edge region being at a radius of greater than 145 mm from a center of the substrate 102. The treatment laser 170 is configured to toggle (e.g., changed) between a first state (e.g., a first power level) and a second state (e.g., a second power level), or to gradually increase/decrease power, in order to reduce edge non-uniformity of the deposited film. In some embodiments, the treatment laser 170 may be covered by a shutter to prevent the laser from interacting with the substrate 102. The laser power is toggled between the first state and the second state, or increased/decreased in power, based on the rotational angle of the substrate 102, i.e., the treatment laser 170 is toggled between the first state and the second state, or increased/decreased in power, every 45°. The first state may be greater than 0%, such as about 30% to 100% of the total power of the treatment laser 170, while the second state may be less than 100%, such as about 0% (e.g., “off”) to about 70% of the total power of the treatment laser 170. The power of the first state is greater than the power of the second state. The rotational angle used may be a consistent rotational angle, e.g., every 45°, or may be altered in each toggle cycle. The rotational angle initiating a toggle between the first state and the second state may be from about 1° to about 360°. In other embodiments, the plurality of upper lamps 141 are configured to toggle between the first state and the second state, or to gradually increase/decrease power, in order to reduce edge non-uniformity of the deposited film. The reduction of edge non-uniformity is enabled by increasing the temperature of the edge of the substrate 102 using the treatment laser 170.

A first processing volume 136 is formed between the upper window 108 and the substrate support 106. A second processing volume 138 is formed between the substrate support 106 and the lower window 110. The substrate support 106 is disposed in the second processing volume 136. The substrate support 106 includes a top surface on which the substrate 102 is disposed and supported. The substrate support 106 is attached to a shaft 118. The shaft 118 is connected to a motion assembly 121. The motion assembly 121 includes one or more actuators and/or adjustment devices that provide movement and/or adjustment of the shaft 118 and/or the substrate support 106 within the second processing volume 136.

The substrate support 106 may include lift pin holes 107 disposed therein. The lift pin holes 107 are sized to accommodate a lift pin 132 for lifting of the substrate 102 from the substrate support 106 either before or after an epitaxial deposition operation or epitaxial etching operation is conducted using the chamber 100. The lift pins 132 may rest on lift pin stops 134 when the substrate support 106 is lowered from a process position to a transfer position.

The flow module 112 includes a cross flow inlet port 180 (e.g., a first inlet port) including a plurality of first process gas inlets 184, a primary inlet port 114 (e.g., a second inlet port) including a plurality of second process gas inlets 188, a plurality of purge gas inlets 164, and one or more exhaust gas outlets 116. The cross flow inlet port 180 enables increased epitaxial growth rates at the area of the substrate 102 near the cross flow inlet port 180. The primary inlet port 114 and the plurality of purge gas inlets 164 are disposed on the opposite sides of the flow module 112 from the one or more exhaust gas outlets 116. The primary inlet port 114 enables epitaxial deposition to occur over the surface of the substrate 102. A gas flow path is formed from the primary inlet port 114 to the exhaust gas outlets 116 in a first direction 190. In various embodiments, the cross flow inlet port 180 is configured with respect to the primary inlet port 114 to provide a second process gas at an angle to the first process gas provided by the primary inlet port 114. The cross flow inlet port 180 and the primary inlet port 114 can be separated by an azimuthal angle of up to about 145 degrees on either side of the chamber.

The primary inlet port 114 is configured to provide a first process gas over a top surface 150 of the substrate 102 in a first direction 190. As used herein, the term process gas refers to both a singular gas and a mixture of multiple gases. Also as used herein, the term “direction’ can be understood to mean the direction in which a process gas exits an inlet port. In some embodiments, the first direction 190 is parallel to the top surface 150 of the substrate 102 and generally pointed towards the opposing exhaust gas outlets 116.

The primary inlet port 114 may comprise a single port, where the first process gas is provided therethrough, or may comprise the plurality of second process gas inlets 188. In some embodiments, the number of second process gas inlets 188 is up to about 5 inlets, although greater or fewer secondary inlets may be provided (e.g., one or more). Each second process gas inlets 188 may provide the first process gas, which may, for example, be a mixture of several process gases. Alternatively, one or more second process gas inlets 188 may provide one or more process gases that are different than at least one other second process gas inlets 188. In some embodiments, the process gases may mix substantially uniformly after exiting the primary inlet port 114 to form the first process gas. In some embodiments, the process gases may generally not mix together after exiting the primary inlet port 114 such that the first process gas has a purposeful, non-uniform composition. Flow rate, process gas composition, and the like, at each second process gas inlets 188 may be independently controlled. In some embodiments, some of the second process gas inlets 188 may be idle or pulsed during processing, for example, to achieve a desired flow interaction with a second process gas provided by the cross flow inlet port 180. Further, in embodiments where the primary inlet port 114 comprises a single port, the single port may be pulsed for similar reasoning.

The cross flow inlet port 180 may be substantially similar in design to the primary inlet port 114. The cross flow inlet port 180 is configured to provide a second process gas in a second direction 182 different from the first direction 190. The second direction 182 is oriented at an angle relative to the first directions 190 such that the second direction 182 is non-parallel to the first directions 190. For example, the angle may be between 45 degrees and 135 degrees, such as a perpendicular angle of 90 degrees. The cross flow inlet port 180 may comprise a single port. Alternatively, the cross flow inlet port 180 may comprise a plurality of first process gas inlets 184. Each first process gas inlets 184 may provide the second process gas, which may for example be a mixture of several process gases. Alternatively, one or more first process gas inlets 184 may provide one or more process gases that are different than at least one other first process gas inlets 184. In some embodiments, the process gases may mix substantially uniformly after exiting the cross flow inlet port 180 to form the second process gas. In some embodiments, the process gases may generally not mix together after exiting the cross flow inlet port 180 such that the second process gas has a purposeful, non-uniform composition. Flow rate, process gas composition, and the like, at each first process gas inlets 184 may be independently controlled. In some embodiments, the cross flow inlet port 180, or some or all of the first process gas inlets 184, may be idle or pulsed during processing, for example, to achieve a desired flow interaction with the first process gas provided by the primary inlet port 114.

One or more flow guides can be disposed below the primary inlet port 114 and the one or more exhaust gas outlets 116. The flow guides can be disposed above the purge gas inlets 164. A liner 163 is disposed on the inner surface of the flow module 112 and protects the flow module 112 from reactive gases used during epitaxial deposition operations or epitaxial etching operations. The primary inlet port 114 and the purge gas inlets 164 are positioned to flow a gas parallel to the top surface 150 of the substrate 102 disposed within the second processing volume 136. The primary inlet port 114 is fluidly connected to a process gas source 151 via a first mass flow controller (MFC) 158 and a carrier gas source 153 via a second MFC 159. In some embodiments, the cross flow inlet port 180 is fluidly connected to the process gas source 151 via a third MFC 165 and the carrier gas source 153 via a fourth MFC 166. In other embodiments, the cross flow inlet port 180 is fluidly connected to a second process gas source (not shown). The purge gas inlets 164 are fluidly connected to a purge gas source 162.

The one or more exhaust gas outlets 116 are fluidly connected to an exhaust pump 157. The one or more exhaust gas outlets 116 are further connected to, or include, an exhaust system 178. The exhaust system 178 fluidly connects the one or more exhaust gas outlets 116 and the exhaust pump 157. The exhaust system 178 as described herein can include one or more growth monitors and can be configured to assist in the controlled epitaxial deposition or epitaxial etching of a layer on the substrate 102.

The chamber 100 includes a pre-heat ring 174 disposed in the second processing volume 136. During the epitaxial deposition operation or epitaxial etching operation, one or more process gases are supplied using the process gas source 151 and one or more carrier gases are supplied using the carrier gas source 153. The one or more process gases and one or more carrier gases flow over the pre-heat ring 174 and over the top surface 150 of the substrate 102 while the second processing volume 136 and the substrate 102 are heated using the lamps 141, 143 to epitaxially deposit (e.g., grow) one or more film layers on the substrate 102. The epitaxially deposited film layers can include one or more of silicon (Si), silicon-germanium (SiGe), silicon phosphide (SiP), silicon arsenide (SiAs), and/or boron doped silicon-germanium (SiGeB).

In some embodiments, the process gas and the carrier gas from the process gas source 151 and carrier gas source 153 are periodically toggled (e.g., changed) between a first state and a second state to supply the process gas and carrier gas intermittently in order to reduce edge non-uniformity of the deposited film. The flow rate of the process gas and the carrier gas may be toggled between the first state (e.g., a first flow rate) and the second state (e.g., the second flow rate) from either or both of the primary inlet port 114 or the cross flow inlet port 180. In the first state, the flow rate of the process gas flow and carrier gas flow are about 30% to 100% of the maximum flow rate of a mass flow controller (MFC) that provides the gas, such as about 80% to 100% of the maximum flow rate of the MFC, such as about 90% of the maximum flow rate of the MFC. In the second state, the flow rate of the process gas flow and carrier gas flow are 0% (e.g., may be “off”) to about 80% of the MFC, such as about 0% to about 20% of the maximum flow rate of the MFC, such as about 10% of the maximum flow rate of the MFC. The flow rate of the first state is greater than the flow rate of the second state. The maximum flow rate of the MFC may be from about 35 sccm to about 10,000 sccm.

In some embodiments, both the carrier gas and the process gas are toggled between the first state and the second state, while in other embodiments, the carrier gas continues to flow while the process gas is toggled between the first state and the second state. The process gas, and in some embodiments, the carrier gas are toggled between the first state and the second state based on the rotational angle of the substrate 102, i.e., the process gas, and in some embodiments, the carrier gas are toggled between the first state and the second state every 45°. The rotational angle used may be a consistent rotational angle, e.g., every 45°, or may be altered in each toggle cycle. The rotational angle initiating a toggle between the first state and the second state may be from about 1° to about 720°.

The one or more process gases can include one or more of dichlorosilane, silane, disilane, germane, and/or hydrogen chloride. In some embodiments, which can be combined with other embodiments, the epitaxial deposition operation or epitaxial etching operation conducted using the chamber 100 includes exposing the substrate 102 to a hydrogen-containing gas at a second temperature and the atmospheric pressure. One or more carrier gases include oxygen (O₂), nitrogen (N₂), hydrogen (H₂), or combinations thereof.

The epitaxial deposition operation or epitaxial etching operation is conducted while maintaining the second processing volume 136 at the second temperature. The second temperature is within a range of 400 degrees Celsius to 1,200 degrees Celsius. In some embodiments, which can be combined with other embodiments, the second temperature is within a range of 400 degrees Celsius to 800 degrees Celsius. In some embodiments, which can be combined with other embodiments, the second temperature is less than 400 degrees Celsius. In an implementation where the atmospheric pressure is used, the epitaxial deposition operation or epitaxial etching operation is conducted while maintaining the second processing volume 136 at the atmospheric pressure. In some embodiments, which can be combined with other embodiments, the atmospheric pressure is within a range of 700 Torr to 800 Torr, such as 720 Torr to 790 Torr, such as 740 Torr to 780 Torr, such as 750 Torr to 770 Torr. In some embodiments, which can be combined with other embodiments, the atmospheric pressure is 760 Torr.

The chamber 100 includes the controller 120 configured to control the chamber 100 or components thereof. For example, the controller 120 may control the operation of the chamber 100. In operation, the controller 120 enables data collection and feedback from the chamber 100 to coordinate and control performance of the chamber 100.

The controller 120 in configured to receive data or input as sensor readings from each of the plurality of sensors and the encoder. The controller 120 is equipped with or in communication with a system model of the chamber 100. The system model includes a heating module and a gas flow module. The system model is a program configured to estimate the gas flow and heating within the chamber 100 through a deposition process or etching process. The controller 120 is further configured to store reading and calculations.

The readings and calculation includes previous sensor readings as well as any other previous sensor readings within the chamber 100. The readings and calculations further include the stored calculated values from after the sensor readings are measured by the controller 120 and run through the system model. Therefore, the controller 120 is configured to both retrieve stored readings and calculation as well as save readings and calculation for future use. Maintaining previous readings and calculation enables the controller 120 to adjust the system model over time to reflect a more accurate version of the chamber 100.

The controller 120 generally includes a central processing unit (CPU), a memory, and support circuits. The CPU may be one of any form of a general purpose processor that can be used in an industrial setting. The memory, or non-transitory computer-readable medium, is accessible by the CPU and may be one or more of memory such as random access memory (RAM), read only memory (ROM), floppy disk, hard disk, or any other form of digital storage, local or remote. The support circuits are coupled to the CPU and may comprise cache, clock circuits, input/output subsystems, power supplies, and the like. The controller 120 monitors the precursor gas, the process gas, the purge gas, and the carrier gas. Support circuits are coupled to the CPU for supporting the processor in a conventional manner. In some embodiments, the controller 120 includes multiple controllers 120, such that the stored readings and calculations and the system model are stored within a separate controller from the controller 120, which operates the chamber 100. In other embodiments, all of the system model and the stored readings and calculations are saved within the controller 120.

The controller 120 is configured to control the heating and gas flow through the chamber 100 by controlling aspects of the lamps, gas flow controls (e.g., the mass flow controller), and the treatment laser 170. The lamps and gas flow controls include the upper lamps 141, the lower lamps 143, the process gas source 151, the carrier gas source 153, the purge gas source 162, and the exhaust pump 157. The controller 120 may also control the motion assembly 121 within the chamber 100.

The controller 120 is configured to adjust the output to each of the lamps, the treatment laser 170, and gas flow controls based off the sensor readings, the system model, and the stored readings and calculations. The controller 120 includes embedded software and a compensation algorithm to calibrate the chamber 100. The controller 120 may include a machine-learning algorithm and may use a regression or clustering technique. The algorithm may be an unsupervised or a supervised algorithm.

The various methods (such as the method 400) and operations disclosed herein may generally be implemented under the control of the CPU by the CPU executing computer instruction code stored in the memory (or in memory of a particular processing chamber) as, e.g., a software routine. When the computer instruction code is executed by the CPU, the CPU controls the chambers to conducted processes in accordance with the various methods and operations described herein. In some embodiments, which can be combined with other embodiments, the memory includes instructions stored therein that, when executed, cause the methods (such as the method 400) and operations described herein to be conducted.

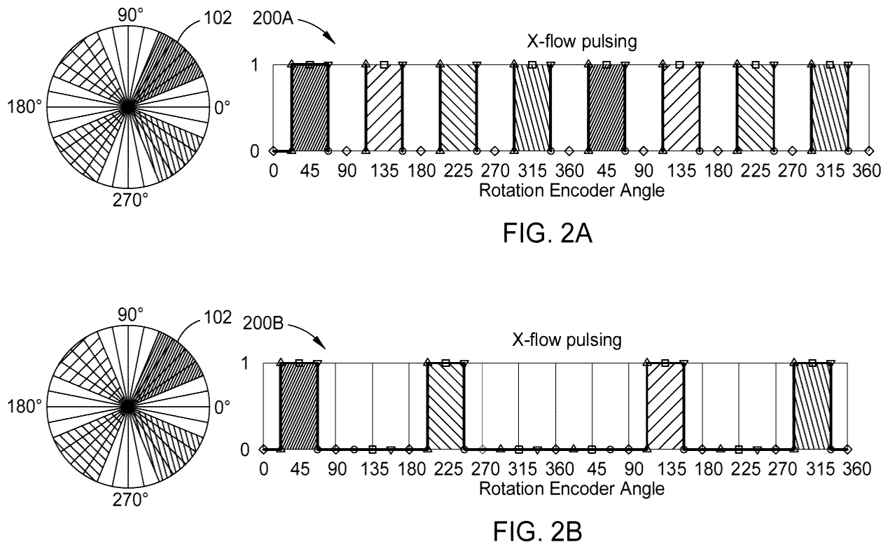

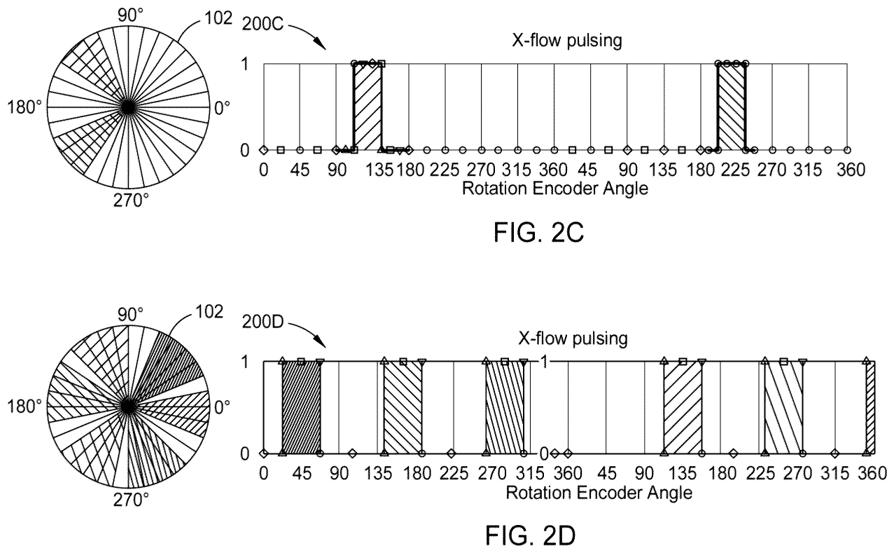

FIG. 2A is a graph of a sequential quadrant flow scheme 200A and a resultant formation region on the substrate 102. During the sequential quadrant flow scheme 200A, the controller 120 is configured to toggle the process gas supplied to the cross flow inlet port 180 from the process gas source 151 between the first state (i.e., supplying process gas) and the second state (i.e., not supplying process gas) to promote film formation at the edge of the substrate 102 approximately every 45° of rotation. The controller 120 controls the flow rate to the cross flow inlet port 180 by controlling the flow rate through the third MFC 165 based on the angle of rotation. In some embodiments, the flow rate of the primary inlet port 114 is constant while the controller toggles the process gas flow rate to the cross flow inlet port 180. In other embodiments, the controller 120 is configured to toggle the process gas supplied to the primary inlet port 114 from the first state to the second state by controlling the flow rate through the first MFC 158 based on the angle of rotation. In other embodiments, the controller 120 is configured to toggle the carrier gas supplied to the primary inlet port 114 and the cross flow inlet port 180 from the first state to the second state by controlling the flow rate through the second MFC 159 and the fourth MFC 166, respectively, based on the angle of rotation. Toggling the flow rate of the process gas from the cross flow inlet port 180 between the first state and the second state promotes the formation of the film at the edge of the substrate 102 in order to correct for non-uniformity in the film, which may be caused by the constant flow rate of the process gas being supplied by the primary inlet port 114.

Toggling the flow rate of the process gas from the cross flow inlet port 180 between the first state and the second state promotes formation of the film at the edge of the substrate 102 from the rotational angle of about 22.5° to about 67.5° during the first toggle cycle, promotes formation of the film at the edge of the substrate 102 from the rotational angle of about 112.5° to about 157.5° during the second toggle cycle, promotes formation of the film at the edge of the substrate 102 from the rotational angle of about 202.5° to about 247.5° during the third toggle cycle, and promotes formation of the film at the edge of the substrate 102 from the rotational angle of about 292.5° to about 337.5° during the fourth toggle cycle. The first, second, third, and fourth toggle cycles occur during a first rotation cycle of the substrate 102. The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During the sequential quadrant flow scheme 200A, the duty cycle for the process gas source 151 is about 50%. The zero-shift during the sequential quadrant flow scheme 200A is about 22.5°.

In some embodiments, during a second rotation cycle of the substrate 102, the controller 120 is configured to toggle the flow rate of the process gas from the cross flow inlet port 180 between the first state and the second state at a second set of rotational angles in order to promotes formation of the film over the portions of the edge of the substrate 102 upon which the film was not deposited during the first rotation cycle. For example, the controller 120 is configured to toggle the flow rate of the process gas between the first state and the second state to promote formation of the film at the edge of the substrate 102 from the rotational angle of about 0° to about 22.5° during the fifth toggle cycle, promote formation of the film at the edge of the substrate 102 from the rotational angle of about 67.5° to about 112.5° during the sixth toggle cycle, promote formation of the film at the edge of the substrate 102 from the rotational angle of about 157.5° to about 202.5° during the seventh toggle cycle, and promote formation of the film at the edge of the substrate 102 from the rotational angle of about 247.5° to about 292.5° during the eighth toggle cycle. In some embodiments, the first rotation cycle is repeated after completion of the second rotation cycle in order to continue depositing the film. In between the first rotation cycle and the second rotation cycle, the controller 120 is configured to toggle the flow rate of the process gas from the cross flow inlet port 180 to the second state for the rotation between about 337.5° and about 360° to enable a shift in the formation regions between the first rotation cycle and the second rotation cycle.

FIG. 2B is a graph of an alternate quadrant flow scheme 200B and a formation resultant region on the substrate 102. During the alternate quadrant flow scheme 200B, the controller 120 is configured to toggle the process gas supplied to the cross flow inlet port 180 from the process gas source 151 between the first state and the second state to promote film formation at the edge of the substrate 102 approximately every 180° of rotation. The controller 120 controls the flow rate to the cross flow inlet port 180 by controlling the flow rate through the third MFC 165 based on the angle of rotation. In some embodiments, the flow rate of the primary inlet port 114 is constant while the controller toggles the process gas flow rate to the cross flow inlet port 180. In other embodiments, the controller 120 is configured to toggle the process gas supplied to the primary inlet port 114 from the first state to the second state by controlling the flow rate through the first MFC 158 based on the angle of rotation. In other embodiments, the controller 120 is configured to toggle the carrier gas supplied to the primary inlet port 114 and the cross flow inlet port 180 from the first state to the second state by controlling the flow rate through the second MFC 159 and the fourth MFC 166, respectively, based on the angle of rotation. Toggling the flow rate of the process gas from the cross flow inlet port 180 between the first state and the second state promotes the formation of the film at the edge of the substrate 102 in order to correct for non-uniformity in the film, which may be caused by the constant flow rate of the process gas being supplied by the primary inlet port 114.

Toggling the flow rate of the process gas from the cross flow inlet port 180 between the first state and the second state promotes the formation of the film at the edge of the substrate 102 from the rotational angle of about 22.5° to about 67.5° during the first toggle cycle and promotes formation of the film at the edge of the substrate 102 from the rotational angle of about 202.5° to about 247.5° during a second toggle cycle during a first rotation cycle of the substrate 102. During a second rotation cycle of the substrate 102, toggling the flow rate of the process gas from the cross flow inlet port 180 between the first state and the second state promotes the formation of the film at the edge of the substrate 102 from the rotational angle of about 112.5° to about 157.5° during the third toggle cycle, and promotes formation of the film at the edge of the substrate 102 from the rotational angle of about 292.5° to about 337.5° during the fourth toggle cycle. Between the first rotation cycle and the second rotation cycle, the controller 120 is configured to toggle the flow rate of the process gas from the cross flow inlet port 180 to the second state for the rotation between about 247.5° and about 112.5° to enable a shift in the formation regions between the first rotation cycle and the second rotation cycle.

The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During the sequential quadrant flow scheme 200A, the duty cycle for the process gas source 151 is about 50%. The zero-shift during the alternate quadrant flow scheme 200B is about 22.5°.

In some embodiments, during a third rotation cycle of the substrate 102, the controller 120 is configured to toggle the flow rate of the process gas between the first state and the second state at a second set of rotational angles in order to promote formation of the film the film over the portions of the edge of the substrate 102 upon which the film was not deposited during the first rotation cycle and the second rotation cycle. For example, the controller 120 is configured to toggle the flow rate of the process gas between the first state and the second state to promote the formation of the film at the edge of the substrate 102 from the rotational angle of about 0° to about 22.5° during the fifth toggle cycle promotes formation of the film at the edge of the substrate 102 from the rotational angle of about 157.5° to about 202.5° during the sixth toggle cycle during a third rotation cycle. Further, the controller 120 is configured to toggle the flow rate of the process gas between the first state and the second state to promote the formation of the film at the edge of the substrate 102 from the rotational angle of about 67.5° to about 112.5° during the seventh toggle cycle and promotes formation of the film at the edge of the substrate 102 from the rotational angle of about 247.5° to about 292.5° during the eighth toggle cycle during a fourth rotation cycle. In some embodiments, the first rotation cycle is repeated after completion of the fourth rotation cycle in order to continue depositing the film. In between the second rotation cycle and the third rotation cycle, the controller 120 is configured to toggle the process gas source 151 to the second state for the rotation between about 337.5° and about 360° to enable a shift in the formation regions between the second rotation cycle and the third rotation cycle.

FIG. 2C is a graph of a single quadrant per cycle flow scheme 200C and a resultant formation region on the substrate 102. During the single quadrant per cycle flow scheme 200C, the controller 120 is configured to toggle the process gas supplied to the cross flow inlet port 180 from the process gas source 151 between the first state and the second state in order to promote film formation at the edge of the substrate 102 approximately every 450°. The controller 120 controls the flow rate to the cross flow inlet port 180 by controlling the flow rate through the third MFC 165 based on the angle of rotation. In some embodiments, the flow rate of the primary inlet port 114 is constant while the controller toggles the process gas flow rate to the cross flow inlet port 180. In other embodiments, the controller 120 is configured to toggle the process gas supplied to the primary inlet port 114 from the first state to the second state by controlling the flow rate through the first MFC 158 based on the angle of rotation. In other embodiments, the controller 120 is configured to toggle the carrier gas supplied to the primary inlet port 114 and the cross flow inlet port 180 from the first state to the second state by controlling the flow rate through the second MFC 159 and the fourth MFC 166, respectively, based on the angle of rotation. Toggling the flow rate of the process gas from the cross flow inlet port 180 between the first state and the second state promotes the formation of the film at the edge of the substrate 102 in order to correct for non-uniformity in the film, which may be caused by the constant flow rate of the process gas being supplied by the primary inlet port 114.

The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During the single quadrant per cycle flow scheme 200C, the duty cycle for the process gas source 151 is about 50%. The zero-shift during the sequential quadrant flow scheme 200A is about 22.5°.

The controller 120 is configured to toggle the flow rate of the process gas from the cross flow inlet port 180 between the first state and the second state to promote the formation of the film at the edge of the substrate 102 from the rotational angle of about 112.5° to about 157.5° during a first toggle cycle and a first rotation cycle of the substrate 102 and promote formation of the film at the edge of the substrate 102 from the rotational angle of about 202.5° to about 247.5° during a second toggle cycle and a second rotation of the substrate 102. Further, during a third toggle cycle and a third rotation cycle of the substrate 102, toggling the flow rate of the process gas between first state and the second state promotes the formation of the film at the edge of the substrate 102 from the rotational angle of about 292.5° to about 337.5° and promotes formation of the film at the edge of the substrate 102 from the rotational angle of about 22.5° to about 67.5° during the fourth toggle cycle and fourth rotation cycle.

In some embodiments, during a fourth rotation cycle of the substrate, the controller is configured to toggle the flow rate of the process gas from the cross flow inlet port 180 between the first state and the second state at a second set of rotational angles in order to deposit the film over the portions of the edge of the substrate 102 upon which the film was not deposited during the first, second, third, and fourth rotation cycles. For example, the controller 120 is configured to toggle the flow rate of the process gas between the first state and the second state to promote the formation of the film at the edge of the substrate 102 from the rotational angle of about 67.5° to about 112.5° during the fifth toggle cycle and fifth rotation cycle and promotes formation of the film at the edge of the substrate 102 from the rotational angle of about 157.5° to about 202.5° during the sixth toggle cycle and a sixth rotation cycle. Further, the controller 120 is configured to toggle the flow rate of the process gas between the first state and the second state to promote the formation of the film at the edge of the substrate 102 from the rotational angle of about 247.5° to about 292.5° during the seventh toggle cycle and rotation cycle, and promote formation of the film at the edge of the substrate 102 from the rotational angle of about 337.5° to about 22.5° during the eighth toggle cycle during a eighth rotation cycle. In some embodiments, the first rotation cycle is repeated after completion of the eighth rotation cycle in order to continue depositing the film. In between the fourth rotation cycle and the fifth rotation cycle, the controller 120 is configured to toggle the process gas source 151 to the second state for the rotation between about 22.5° and about 112.5° to enable a shift in the formation regions between the fourth rotation cycle and the fifth rotation cycle.

FIG. 2D is a graph of an alternative sequential quadrant flow scheme 200D and a resultant formation region on the substrate 102. During the sequential quadrant flow scheme 200D, the controller 120 is configured to toggle the process gas supplied to the cross flow inlet port 180 from the process gas source 151 between the first state and the second state to promote film formation at the edge of the substrate 102 approximately every 120° of rotation. The controller 120 controls the flow rate to the cross flow inlet port 180 by controlling the flow rate through the third MFC 165 based on the angle of rotation. In some embodiments, the flow rate of the primary inlet port 114 is constant while the controller toggles the process gas flow rate to the cross flow inlet port 180. In other embodiments, the controller 120 is configured to toggle the process gas supplied to the primary inlet port 114 from the first state to the second state by controlling the flow rate through the first MFC 158 based on the angle of rotation. In other embodiments, the controller 120 is configured to toggle the carrier gas supplied to the primary inlet port 114 and the cross flow inlet port 180 from the first state to the second state by controlling the flow rate through the second MFC 159 and the fourth MFC 166, respectively, based on the angle of rotation. Toggling the flow rate of the process gas from the cross flow inlet port 180 between the first state and the second state promotes the formation of the film at the edge of the substrate 102 in order to correct for non-uniformity in the film, which may be caused by the constant flow rate of the process gas being supplied by the primary inlet port 114.

Toggling the flow rate of the process gas from the cross flow inlet port 180 between the first state and the second state promotes the formation of the film at the edge of the substrate 102 from the rotational angle of about 22.5° to about 67.5° during the first toggle cycle, promotes formation of the film at the edge of the substrate 102 from the rotational angle of about 142.5° to about 187.5° during the second toggle cycle, and promotes formation of the film at the edge of the substrate 102 from the rotational angle of about 262.5° to about 307.5° during the third toggle cycle. The first, second, and third toggle cycles occur during a first rotation cycle of the substrate 102.

The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During the sequential quadrant flow scheme 200A, the duty cycle for the process gas source 151 is about 50%. The zero-shift during the sequential quadrant flow scheme 200A is about 22.5°.

In some embodiments, during a second rotation cycle of the substrate 102, the process gas source 151 is configured to toggle the flow rate of the process gas from the cross flow inlet port 180 between the first state and the second state at a second set of rotational angles in order to deposit the film over the portions of the edge of the substrate 102 upon which the film was not deposited during the first rotation cycle. For example, the controller 120 is configured to toggle the flow rate of the process gas from the cross flow inlet port 180 between the first state and the second state to promote the formation of the film at the edge of the substrate 102 from the rotational angle of about 112.5° to about 157.5° during the fourth toggle cycle, promote formation of the film at the edge of the substrate 102 from the rotational angle of about 232.5° to about 277.5° during the fifth toggle cycle, and promote formation of the film at the edge of the substrate 102 from the rotational angle of about 352.5° to about 397.5° during the sixth toggle cycle. In some embodiments, the first rotation cycle is repeated after completion of the second rotation cycle in order to continue depositing the film.

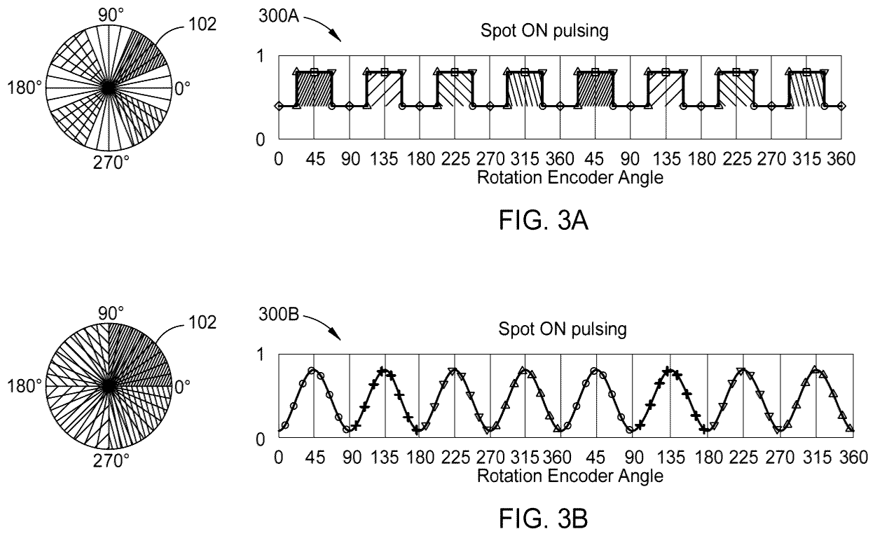

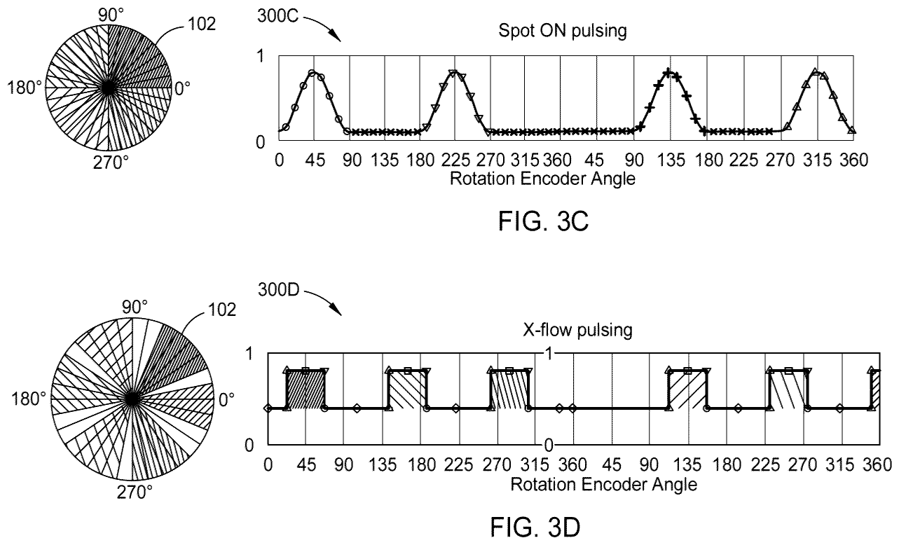

FIG. 3A is a graph of a sequential square pulse scheme 300A and a resultant formation region on the substrate 102. During sequential square pulse scheme 300A, the controller 120 is configured to toggle the treatment laser 170 between the first state and the second state approximately every 45° of rotation. In some embodiments, when the treatment laser 170 is toggled first, the treatment laser 170 is emitting at about 80% of the total power of the treatment laser 170. Further, in some embodiments, when the treatment laser 170 is toggled to the second state, the treatment laser is emitting about 40% of the total power of the treatment laser 170. Toggling between the first state and the second state promotes film formation at the edge of the substrate 102 of the film from the rotational angle of about 22.5° to about 67.5° during the first toggle cycle, formation of the film from the rotational angle of about 112.5° to about 157.5° during the second toggle cycle, formation of the film from the rotational angle of about 202.5° to about 247.5° during the third toggle cycle, and formation of the film from the rotational angle of about 292.5° to about 337.5° during the fourth toggle cycle. The first, second, third, and fourth toggle cycles occur during a first rotation cycle of the substrate 102.

The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During the sequential square pulse scheme 300A, the duty cycle for the process gas source 151 is about 50%. The zero-shift during the sequential square pulse scheme 300A is about 22.5°.

In some embodiments, during a second rotation cycle of the substrate 102, the treatment laser 170 is configured to toggle between the first state and the second state at a second set of rotational angles in order to deposit the film over the portions of the substrate 102 upon which the film was not deposited during the first rotation cycle. For example, the controller 120 is configured to toggle the treatment laser 170 between the first state and the second state to promote the formation of the film at the edge of the substrate 102 from the rotational angle of about 0° to about 22.5° during the fifth toggle cycle, formation of the film from the rotational angle of about 67.5° to about 112.5° during the sixth toggle cycle, formation of the film from the rotational angle of about 157.5° to about 202.5° during the seventh toggle cycle, and formation of the film from the rotational angle of about 247.5° to about 292.5° during the eighth toggle cycle. In some embodiments, the first rotation cycle is repeated after completion of the second rotation cycle in order to continue depositing the film. In between the first rotation cycle and the second rotation cycle, the controller 120 is configured to toggle treatment laser 170 to the second state for the rotation between about 337.5° and about 360° to enable a shift in the formation regions between the first rotation cycle and the second rotation cycle.

FIG. 3B is a graph of a sequential sinusoidal pulse scheme 300B and a resultant formation region on the substrate 102. During the sequential sinusoidal pulse scheme 300B, the controller 120 is configured to gradually (e.g., sinusoidally) toggle the treatment laser 170 between the first state and the second state to promote formation of the film at the edge of the substrate 102 approximately every 180° of rotation. In some embodiments, the treatment laser 170 gradually toggles between about 80% of the total power and 10% of the total power of the treatment laser 170. Toggling between first state and the second state promotes peak film formation (e.g., the highest rate of deposition) at the edge of the substrate 102 from the rotational angle of about 22.5° to about 67.5° during the first toggle cycle, peak formation of the film from the rotational angle of about 112.5° to about 157.5° during the second toggle cycle, peak formation of the film from the rotational angle of about 202.5° to about 247.5° during the third toggle cycle, and peak formation of the film from the rotational angle of about 292.5° to about 337.5° during the fourth toggle cycle during a first rotation cycle of the substrate 102. Between the first rotation cycle and the second rotation cycle, the controller 120 is configured to toggle the treatment laser 170 to the second state for the rotation between about 247.5° and about 112.5° to enable a shift in the formation regions between the first rotation cycle and the second rotation cycle.

The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During sequential sinusoidal pulse scheme 300B, the duty cycle for the process gas source 151 is about 50%. The zero-shift during the sequential sinusoidal pulse scheme 300B is 0°.

In some embodiments, during a third rotation cycle of the process gas source 151 is configured to toggle between the first state and the second state at a second set of rotational angles in order to deposit the film over the portions of the substrate 102 which did not experience peak formation during the first rotation cycle. For example, the controller 120 is configured to toggle the process gas source 151 between the first state and the second state to promote peak formation of the film from at the edge of the substrate 102 the rotational angle of about 0° to about 22.5° during the fifth toggle cycle, peak formation of the film from the rotational angle of about 67.5° to about 112.5° during the sixth toggle cycle, peak formation of the film from the rotational angle of about 157.5° to about 202.5° during the seventh toggle cycle, and peak formation of the film from the rotational angle of about 247.5° to about 292.5° during the eighth toggle cycle during a second rotation cycle. In some embodiments, the first rotation cycle is repeated after completion of the second rotation cycle in order to continue depositing the film. In between the first rotation cycle and the second rotation cycle, the controller 120 is configured to toggle the treatment laser 170 to the second state for the rotation between about 337.5° and about 360° to enable a shift in the deposition.

FIG. 3C is a graph of the alternate sinusoidal pulse scheme 300C and the resultant formation region on the substrate 102. During the alternate sinusoidal pulse scheme 300C, the controller 120 is configured to gradually (e.g., sinusoidally) toggle the treatment laser 170 between the first state and the second state promotes peak film formation (e.g., the highest rate of deposition) at the edge of the substrate 102 approximately every 180° of rotation. In some embodiments, the treatment laser 170 gradually toggles between about 80% of the total power and 10% of the total power of the treatment laser 170. Toggling between first state and the second state promotes peak formation of the film at the edge of the substrate 102 from the rotational angle of about 22.5° to about 67.5° during the first toggle cycle, peak formation of the film from the rotational angle of about 202.5° to about 247.5° during the second toggle cycle during a first rotation cycle of the substrate 102. During a second rotation cycle of the substrate 102, peak formation of the film occurs from the rotational angle of about 112.5° to about 157.5° during the third toggle cycle, and peak formation of the film from the rotational angle of about 292.5° to about 337.5° during the fourth toggle cycle. Between the first rotation cycle and the second rotation cycle, the controller 120 is configured to toggle the treatment laser 170 to the second state for the rotation between about 247.5° and about 112.5° to enable a shift in the formation regions between the first rotation cycle and the second rotation cycle.

The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During sequential sinusoidal pulse scheme 300B, the duty cycle for the process gas source 151 is about 50%. The zero-shift during the alternate sinusoidal pulse scheme 300C is 0°.

In some embodiments, during a third rotation cycle of the process gas source 151 is configured to toggle between the first state and the second state at a second set of rotational angles in order to deposit the film over the portions of the substrate 102 which did not experience peak formation during the first rotation cycle and the second rotation cycle. For example, the controller 120 is configured to toggle the process gas source 151 between the first state and the second state to promote peak formation of the film at the edge of the substrate 102 from the rotational angle of about 0° to about 22.5° during the fifth toggle cycle and peak formation of the film from the rotational angle of about 157.5° to about 202.5° during the sixth toggle cycle during a third rotation cycle. Further, the controller 120 is configured to toggle the process gas source 151 between the first state and the second state to promote peak formation of the film at the edge of the substrate 102 from the rotational angle of about 67.5° to about 112.5° during the seventh toggle cycle, and formation of the film from the rotational angle of about 247.5° to about 292.5° during the eighth toggle cycle during a fourth rotation cycle. In some embodiments, the first rotation cycle is repeated after completion of the fourth rotation cycle in order to continue depositing the film. In between the second rotation cycle and the third rotation cycle, the controller 120 is configured to toggle the process gas source 151 to the second state for the rotation between about 337.5° and about 360° to enable a shift in the formation regions between the second rotation cycle and the third rotation cycle.

FIG. 3D is a graph of an alternative square pulse scheme 300D and a resultant formation region on the substrate 102. During alternative square pulse scheme 300D, the controller 120 is configured to toggle the treatment laser 170 between the first state and the second state promotes peak film formation (e.g., the highest rate of deposition) at the edge of the substrate 102 approximately every 120° of rotation. In some embodiments, when the treatment laser 170 is toggled first, the treatment laser 170 is emitting at about 80% of the total power of the treatment laser 170. Further, in some embodiments, when the treatment laser 170 is toggled to the second state, the treatment laser is emitting about 40% of the total power of the treatment laser 170. Toggling between first state and the second state promotes the formation of the film at the edge of the substrate 102 from the rotational angle of about 22.5° to about 67.5° during the first toggle cycle, formation of the film from the rotational angle of about 142.5° to about 187.5° during the second toggle cycle, and formation of the film from the rotational angle of about 262.5° to about 307.5° during the third toggle cycle. The first, second, and third toggle cycles occur during a first rotation cycle of the substrate 102.

The controller 120 is further configured to rotate the shaft 118 via the motion assembly 121 at greater than 0 rpm, such as from about 1 to about 120 rpm, such as about 15 to 65 rpm, such as about 25 rpm to about 50 rpm, such as about 65 rpm to about 120 rpm, such as about 75 rpm to about 85 rpm. During the sequential square pulse scheme 300A, the duty cycle for the process gas source 151 is about 50%. The zero-shift during the sequential square pulse scheme 300A is about 22.5°.

In some embodiments, during a second rotation cycle of the substrate 102, the treatment laser 170 is configured to toggle between the first state and the second state at a second set of rotational angles in order to deposit the film over the portions of the substrate 102 upon which the film was not deposited during the first rotation cycle. For example, the controller 120 is configured to toggle the treatment laser 170 between the first state and the second state to promote the formation of the film at the edge of the substrate 102 from the rotational angle of about 112.5° to about 157.5° during the fourth toggle cycle, formation of the film from the rotational angle of about 232.5° to about 277.5° during the fifth toggle cycle, and formation of the film from the rotational angle of about 352.5° to about 397.5° during the sixth toggle cycle. In some embodiments, the first rotation cycle is repeated after completion of the second rotation cycle in order to continue depositing the film.

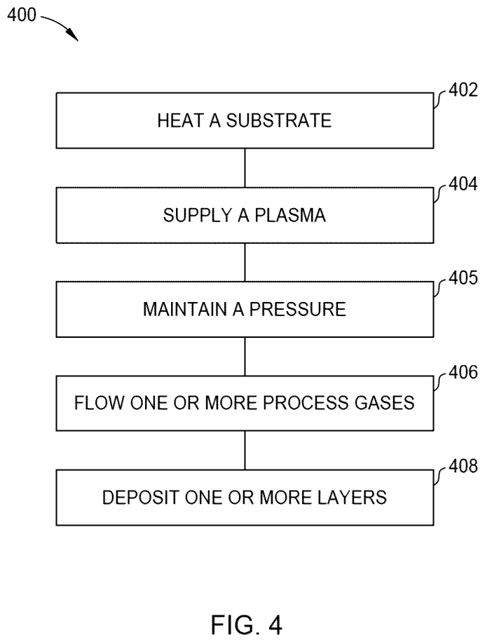

FIG. 4 is a flow diagram of a method 400 of processing a substrate 102. Operation 402 of the method 400 includes heating a substrate 102 positioned on the substrate support 106 of the chamber 100. The substrate 102 is heated from one side of the substrate 102. The heating includes heating the substrate 102 to a target temperature. In one or more embodiments, the target temperature for the substrate 102 is less than 500 degrees Celsius. In one or more embodiments, the target temperature is 400 degrees Celsius or less, such as less than 200 degrees Celsius (for example about 150 degrees Celsius). In one or more embodiments, the target temperature for the substrate 102 is 400 degrees Celsius or higher or 600 degrees Celsius or less. In one or more embodiments, the target temperature for the substrate 102 is within a range of 380 degrees Celsius to 600 degrees Celsius, for example 400 degrees Celsius to 500 degrees Celsius.

Operation 404 includes supplying a one or more process gases in the second processing volume 136 of the chamber 100. The one or more process gases flow over the substrate 102. In some embodiments, the flowing of the one or more process gases over the substrate 102 includes changing the flowing of the one or more process gases between a first flow rate and a second flow rate. In some embodiments, the process gas may be changed between the first flow rate and the second flow rate using one of or a combination of one of the sequential quadrant flow scheme 200A, the alternate quadrant flow scheme 200B, single quadrant per cycle flow scheme 200C, or alternative sequential quadrant flow scheme 200D.

Operation 405 includes maintaining the processing volume at a pressure. In one or more embodiments, the pressure is maintained to be less than 60 Torr, such as within a range of 0 Torr to 30 Torr. In one or more embodiments, the pressure is maintained to be less than 1 Torr, such as within a range of 0 Torr to 5 mTorr.

Operation 406 includes flowing one or more process gases flowing over the substrate 102 are heated. In some embodiments, the heating of the one or more process gases over the substrate includes changing a power level of a treatment laser between a first power level and a second power level. In some embodiments, the process gas may be changed between the first power level and the second power level using a one of or a combination of one of the sequential square pulse scheme 300A, sequential sinusoidal pulse scheme 300B, alternate sinusoidal pulse scheme 300C, or alternative square pulse scheme 300D.

Operation 408 includes depositing one or more layers on the substrate 102.

In summation, a method is disclosed. The method include supplying a one or more process gases in a processing volume of a chamber. In some embodiments, a flow of one or more process gases over the substrate is changed between a first flow rate and a second flow rate based on an angle of rotation of the substrate. In some embodiments, a treatment laser substrate is changed between a first power level and a second power level based on an angle of rotation of the substrate to heat the one or more process gases. One or more layers are formed on the substrate. The treatment laser and process gases are configured to change between the first flow rate and the second flow rate, or to gradually increase/decrease power, in order to reduce edge non-uniformity of the deposited film.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A substrate processing system applicable for use in semiconductor manufacturing, comprising:
a chamber comprising a first inlet port to supply one or more process gases to a processing volume;
a substrate support disposed in the processing volume and operable to rotate a substrate disposed on the substrate support; and
a controller to cause a flow of one or more process gases supplied to the processing volume via the first inlet port to change based on an angle of rotation of the substrate.

2. The substrate processing system of claim 1, wherein the flow of one or more process gases supplied to the processing volume changes between a first flow rate and a second flow rate, wherein the first flow rate is greater than the second flow rate.

3. The substrate processing system of claim 2, wherein the second flow rate is 0 sccm.

4. The substrate processing system of claim 1, further comprising a laser to direct a laser beam to an edge region of the substrate, the edge region being at a radius greater than 145 mm from a center of the substrate, wherein the controller causes a power level of the laser beam to change based on the angle of rotation of the substrate.

5. The substrate processing system of claim 4, wherein the power level of the laser beam changes between a first power level and a second power level, wherein the first power level is greater than the second power level.

6. The substrate processing system of claim 5, wherein the second power level is 0% of a total laser power.

7. The substrate processing system of claim 1, further comprising:
an exhaust gas outlet, wherein the first inlet port is oriented at an angle between about 45 degrees and about 135 degrees from the exhaust gas outlet; and
a second inlet port to supply one or more process gases to the processing volume, wherein the second inlet port and the exhaust gas outlet are disposed on opposite sides of the processing volume.

8. A method of substrate processing, comprising:
supplying one or more process gases to a processing volume of a chamber;
rotating a substrate within the processing volume;
changing a flow of the one or more process gases between a first flow rate and a second flow rate based on an angle of rotation of the substrate, wherein the second flow rate is lower than the first flow rate; and
forming one or more layers on the substrate with the one or more process gases.

9. The method of claim 8, wherein the one or more process gases are changed between the first flow rate and the second flow rate approximately every 45° rotation of the substrate.

10. The method of claim 8, wherein the second flow rate is 0 sccm.

11. The method of claim 8, wherein the second flow rate is greater than 0 sccm and less than about 70% of a maximum flow rate of a mass flow controller (MFC) that provides the one or more process gases, wherein the maximum flow rate of the MFC may be from about 35 sccm to about 10,000 sccm.

12. The method of claim 8, wherein the one or more process gases are changed between the first flow rate and the second flow rate approximately every 450° rotation of the substrate.

13. The method of claim 8, wherein rotating the substrate is performed via a motion assembly at about 1 rpm to about 120 rpm.

14. A method of substrate processing, comprising:
supplying one or more process gases to a processing volume of a chamber;
flowing the one or more process gases over a substrate;
rotating the substrate within the processing volume;
directing a laser beam from a laser to an edge region of the substrate, the edge region being at a radius of greater than 145 mm from a center of the substrate;
changing a power of the laser beam between a first power level and a second power level based on an angle of rotation of the substrate, wherein the first power level is higher than the second power level; and
forming one or more layers on the substrate.

15. The method of claim 14, wherein the laser is changed between the first power level and the second power level approximately every 45° of rotation.

16. The method of claim 14, wherein the second power level is 0% of a total power of the laser.

17. The method of claim 14, wherein the laser is changed sinusoidally between the first power level and the second power level approximately every 45° of rotation.

18. The method of claim 14, wherein the second power level is greater than 0% and less than 70% of a total power of the laser.

19. The method of claim 14, wherein the laser is sinusoidally changed between the first power level and the second power level approximately every 180° of rotation.

20. The method of claim 14, wherein the substrate is configured to rotate via a motion assembly at about 1 rpm to about 120 rpm.
